(19) United States
(12) Patent Application Publication
(10) Pub. No.: US 2015/0380258 A1
(43) Pub. Date: Dec. 31, 2015

(54) METHOD FOR CONTROLLING HEIGHT OF A FIN STRUCTURE

(71) Applicants: STMicroelectronics, Inc., Coppell, TX (US); International Business Machines Corporation, Armonk, NY (US); GLOBALFOUNDRIES Inc., Grand Cayman (KY)

(72) Inventors: Qing Liu, Watervliet, NY (US); Ruilong Xie, Schenectady, NY (US); Xiuyu Cai, Niskayuna, NY (US); Chun-chen Yeh, Clifton Park, NY (US); Kejia Wang, Poughkeepsie, NY (US)

(73) Assignees: STMicroelectronics, Inc., Coppell, TX (US); International Business Machines Corporation, Armonk, NY (US); GLOBALFOUNDRIES Inc., Grand Cayman (KY)

(21) Appl. No.: 14/314,384

(22) Filed: Jun. 25, 2014

(51) Int. Cl. H01L 21/308; H01L 29/205; H01L 29/78

(52) U.S. Cl. CPC H01L 21/3086; H01L 29/785; H01L 29/205

(57) ABSTRACT

Methods and structures for forming fin structures whilst controlling the height of the fin structures with high uniformity across large areas are described. According to some aspects, a multi-layer structure comprising a first etch-stop layer and a second etch-stop layer separated from a substrate and from each other by spacer layers is formed on a substrate. Trenches may be formed through the first and second etch-stop layers. A buffer layer may be formed in the trenches, filling the trenches to a level approximately at a position of the first etch-stop layer. A semiconductor layer may be formed above the buffer layer and etched back to the second etch-stop layer to form semiconductor fins of highly uniform heights.

### BACKGROUND

1. Technical Field

The present application relates to methods and structures for forming a fin structure whilst controlling the height of the fin structure, and can be used to form FETs that include fin structures, such as finFETs.

2. Discussion of the Related Art

Transistors are fundamental device elements of modern digital processors and memory devices, and have found numerous applications in various areas of electronics including data processing, data storage, and high-power applications. Currently, there are a variety of transistor types and designs that may be used for different applications. Various transistor types include, for example, bipolar junction transistors (BJT), junction field-effect transistors (JFET), metal-oxide-semiconductor field-effect transistors (MOSFET), vertical channel or trench field-effect transistors, and superjunction or multi-drain transistors.

Two types of transistors have emerged within the MOSFET family of transistors that show promise for scaling to ultra-high density and nanometer-scale channel lengths. One of these transistor types is a so-called fin field-effect transistor or “finFET.” The channel of a finFET is formed as a three-dimensional fin that may extend from a surface of a substrate. FinFETs have favorable electrostatic properties for complimentary MOS (CMOS) scaling to smaller sizes. Because the fin is a three-dimensional structure, the transistor's channel can be formed on three surfaces of the fin, so that the finFET can exhibit a high current switching capability for a given surface area occupied on a substrate. Since the channel and device can be raised from the substrate surface, there can be reduced electric field coupling between adjacent devices as compared to conventional planar MOSFETs.

The second type of transistor is called a fully-depleted, silicon-on-insulator or “FD-SOI” FET. The channel, source, and drain of an FD-SOI FET is formed in a thin planar semiconductor layer that overlies a thin insulator. Because the semiconductor layer and the underlying insulator are thin, the body of the transistor (that lies below the thin insulator) can act as a second gate. The thin layer of semiconductor on insulator permits higher body biasing voltages that can boost performance. The thin insulator also reduces leakage current to the transistor's body region that would otherwise occur in bulk FET devices.

### SUMMARY

The described technology relates to methods and structures for precisely controlling the height of a fin structure. In some cases, the technology may be used to form field-effect transistors including fins having uniform heights (e.g., within 5% of one another, or less) across a semiconductor die. A plurality of etch-stop layers may be formed on a substrate and spaced apart at a known distance. These etch-stop layers may be used as height guides during formation of fins on the substrate. Fins may be formed in trenches etched through the etch-stop layers. A final height of the fins may be determined by removing excess fin material to a level of one of the etch-stop layers.

According to some embodiments, a fin structure may be formed that includes a semiconductor layer comprising a III-V semiconductor. The methods and structures described herein may provide for repeated formation of such fin structures with minimal variation in the heights of the fins.

According to some embodiments, one or more trenches are formed in a multi-layer structure comprising a first etch-stop layer and a second etch-stop layer, wherein the one or more trenches are formed through the first and second etch-stop layers. A first layer is formed in at least a first trench of the one or more trenches, filling at least the first trench to a level approximately at a position of the first etch-stop layer. A semiconductor layer may be formed in at least the first trench from a material different from the first layer material.

According to some aspects, the one or more trenches are etched in shapes for forming one or more fins for one or more finFETs. According to some implementations, the first layer comprises a buffer layer. According to some implementations, the buffer layer is InP. According to some implementations, the semiconductor layer comprises a III-V semiconductor material. According to some implementations, the III-V semiconductor material is InGaAs.

According to some aspects, a portion of the semiconductor layer may be removed, stopping the removal at the second etch-stop layer, such that the remaining semiconductor layer fills at least the first trench to a level approximately at a position of the second etch-stop layer. According to some embodiments, the multi-layer structure may be further etched to remove the second etch-stop layer and a spacer, stopping the etching at the first etch-stop layer. In some embodiments, the etching to remove the second etch-stop layer exposes the semiconductor layer so as to form at least a first fin for a finFET.

According to some aspects, the first etch-stop layer is deposited, and a spacer having a thickness approximately equal to a selected fin height is deposited on the first etch-stop layer. A second etch-stop layer is then deposited on the spacer. According to some embodiments, a trench is forming having a width between approximately 4 nm and approximately 20 nm. According to some implementations, one or more trenches are etched to a semiconductor substrate.

According to some implementations, the spacer comprises a silicon dioxide. According to some implementations, at least one of the first etch-stop layer and the second etch-stop layer comprises a silicon nitride.

According to some aspects, the first layer comprises a first semiconductor material. The first layer may be formed by growing the first semiconductor material from the semiconductor substrate to overfill at least the first trench, planarizing the first semiconductor material to approximately a level of the second etch-stop layer, and performing an etch to recess the first semiconductor material to approximately a level of the first etch-stop layer.

According to some aspects, a base layer is deposited on the substrate and the first etch-stop layer is deposited on the base layer. The thickness of the base layer may be selected such that crystal defects in the first semiconductor material terminate at approximately the first etch-stop layer.

According to some aspects, forming the semiconductor layer comprises growing a second semiconductor material to overfill at least the first trench in contact with the first semiconductor material, and planarizing the second semiconductor material at the height of the second etch-stop layer.

The foregoing aspects and implementations of acts may be included in any suitable combination in a method for forming a fin structure whilst precisely controlling the height of the fin structure.

According to some embodiments, a structure for forming a finFET comprises a substrate, a first etch-stop layer spaced a first distance from a surface of the substrate, and a second etch-stop layer spaced a second distance from the first etch-stop layer. The structure may further comprise a first trench formed through the first etch-stop layer and the second etch-stop layer and a buffer layer in contact with the substrate and filling at least the first trench approximately to a level of the first etch-stop layer, and a semiconductor layer in contact with the buffer layer. According to some embodiments, the semiconductor layer fills the trench approximately to a level of the second etch-stop layer. According to some embodiments, the structure further comprises a spacer separating the second etch-stop layer from the first etch-stop layer. According to some implementations, the spacer has a thickness between approximately 10 nm and approximately 60 nm. According to some implementations, the spacer comprises a silicon oxide.

According to some aspects, the buffer layer comprises a first III-V semiconductor material. According to some implementations, the first III-V semiconductor material is InP. According to some embodiments, the semiconductor layer comprises a second III-V semiconductor material. According to some implementations, the second III-V semiconductor material is InGaAs. According to some implementations, the first etch-stop layer comprises a silicon nitride.

According to some aspects, the semiconductor layer has a substantially rectangular cross-section. According to some embodiments, the semiconductor layer has a width between 4 nm and 20 nm and a height between 10 nm and 60 nm out of the trench.

The foregoing aspects and implementations may be included in any suitable combination in one or more embodiments of a structure for forming a finFET.

According to some embodiments, a semiconductor die comprises a plurality of fins for finFETs distributed over the die, wherein each of the plurality of fins are formed from a buffer layer and a semiconductor layer formed on the buffer layer. A height of the semiconductor layer over the entire die may be the same to within ±2 nm.

According to some embodiments, the height of the semiconductor layer over the entire die is the same to within ±1 nm.

According to some aspects, the buffer layer is an epitaxial layer formed on a substrate. According to some embodiments, the buffer layer comprises a III-V semiconductor and the substrate comprises silicon. According to some implementations, the buffer layer III-V semiconductor is InP. According to some embodiments, the semiconductor layer comprises a III-V semiconductor. According to some implementations, the semiconductor layer III-V semiconductor is InGaAs.

According to some aspects, defects resulting from epitaxial growth substantially terminate within the buffer layer.

The foregoing aspects and implementations may be included in any suitable combination in one or more embodiments of a semiconductor die including fin structures or finFETs formed thereon.

### BRIEF DESCRIPTION OF DRAWINGS

The skilled artisan will understand that the figures, described herein, are for illustration purposes only. It is to be understood that in some instances various aspects of the embodiments may be shown exaggerated or enlarged to facilitate an understanding of the embodiments. In the drawings, like reference characters generally refer to like features, functionally similar and/or structurally similar elements throughout the various figures. The drawings are not necessarily to scale, emphasis instead being placed upon illustrating the principles of the teachings. Where the drawings relate to microfabrication of integrated devices, only one device may be shown of a large plurality of devices that may be fabricated in parallel. The drawings are not intended to limit the scope of the present teachings in any way.

FIG. 1A is a perspective view depicting a finFET, according to some embodiments;

FIGS. 1B-1E depict cross-sectional views of finFET fins, according to various embodiments;

FIGS. 2A-2H depict process steps that may be used to form a fin structure, according to some embodiments;

FIGS. 3A-B depict an exemplary finFET, in accordance with some embodiments; and

FIG. 4 depicts an exemplary semiconductor die, in accordance with some embodiments.

The features and advantages of the embodiments will become more apparent from the detailed description set forth below when taken in conjunction with the drawings.

### DETAILED DESCRIPTION

An example of a finFET 100 is depicted in the perspective view of FIG. IA, according to some embodiments. A finFET may be fabricated on a bulk semiconductor substrate 110, e.g., a silicon substrate, and comprise a fin-like structure 115 that runs in a length direction along a surface of the substrate and extends in a height direction normal to the substrate surface. The fin 115 may have a narrow width, e.g., less than approximately 50 nanometers. There may be an electrically-insulating layer 105, e.g., an oxide layer, on a surface of the substrate 110. The fin may pass through the insulating layer 105, but be attached to the semiconducting substrate 110 at a lower region of the fin, in some embodiments. A gate structure comprising a conductive gate material 130 (e.g., polysilicon) and a gate insulator 135 (e.g., an oxide) may be formed over a region of the fin. The finFET may further include a source region 120 and drain region 140 adjacent to the gate. A finFET may also include integrated source S, gate G, drain D, and body B (not shown) interconnects to provide electrical connections to the source, gate, drain, and back body regions of the device.

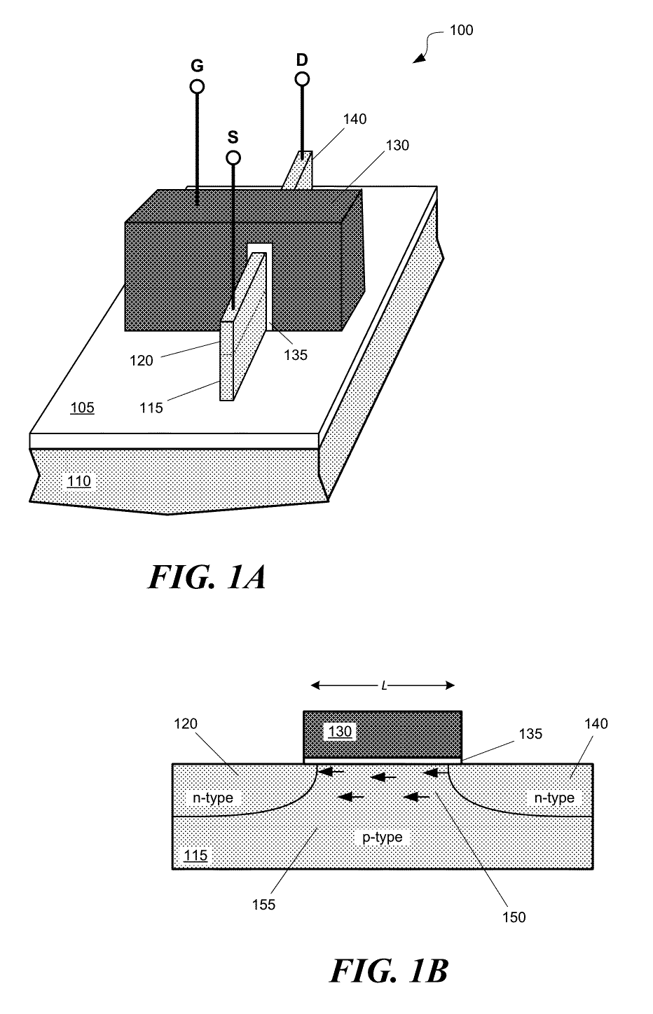

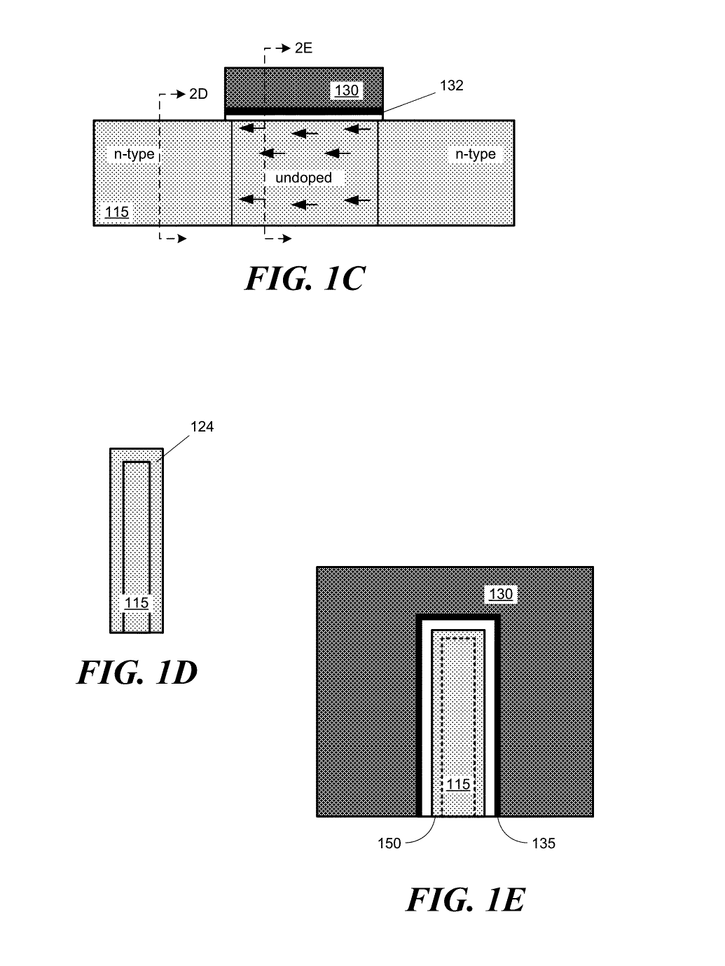

FinFETs like those depicted in FIG. 1A exhibit favorable electrostatic properties for scaling to high-density, low-power, integrated circuits. Because the fin and channel are raised from the substrate, the devices can exhibit reduced cross-coupling between proximal devices. For the device shown in FIG. 1A, the fin 115 may be formed from the bulk substrate 110 by an etching process, and is therefore attached to the substrate at a base region of the fin, a region occluded in the drawing by the adjacent insulator 105. The insulator 105 may be formed after the etching of the fin 115. Because the fin 115 is attached to the semiconductor substrate, leakage current and cross-coupling may occur via the base region of the fin.

Source, channel, and drain regions of a finFET may be doped with impurities to create different regions of different conductivity types, as depicted in FIGS. 1B-1C. Several different configurations of source, channel, and drain regions are possible. According to some embodiments, source region 120 and drain region 140 may be doped to be of a first conductivity type and the channel region 150 may be doped to be of an opposite conductivity type, as depicted in FIG. 1B. The terms “source region” and “drain region” as used may include extension regions of the fins that lie between source and drain contact regions and the channel region of the finFET device.

The finFET may further include a body region 155 that may be of a same conductivity type as the channel region. In some embodiments, a channel region 150 of a finFET may be undoped, as depicted in FIG. 1C. The doping of source and drain regions in a finFET may be of various geometries. As depicted in FIG. 1B, vertical portions of the fin 115 may be doped to form source 120 and drain 140 regions, according to some embodiments. Alternatively, outer sheath portions 124 of a fin 115 may be doped to form source and drain regions, as depicted in FIGS. 1C-1E.

FIG. 1C and FIG. 1E depict a three-dimensional nature of a channel region 150 in a finFET, according to some embodiments. In some embodiments, the entire fin portion encased by the gate structure may be inverted and form a bulk channel rather than a surface channel. A metallic film 132 may be deposited between a gate electrode 130 and gate oxide 135 in some implementations to improve gate conductance and gate switching speeds.

The inventors have recognized that as fin structures become smaller in size, variations in the size of one or more dimensions of a fin have an increasing impact on the performance of a device utilizing the fin structure. For example, a process that produces fin structures with a variability of up to 2 nm in each dimension could produce a first fin with a height of 30 nm and a width of 5 nm, and a second fin with a height of 32 nm and a width of 7 nm. Since a fin structure in a device such as a finFET conduct charges across multiple sides of the fin, the total current flowing across these two exemplary fins when used in an otherwise identical finFET could be quite different in each case. Variations in fin dimensions can lead to unacceptable variations in current flow and leakage current in devices such as memory devices, e.g., SRAM circuits.

The inventors have also recognized that when a fin channel comprises a different type of semiconductor material than a substrate on which the fin is formed, it may be more difficult to consistently form fins and buffer layers with the same height (or substantially the same height) due to defects that form at the interface between the semiconductor material and the substrate. For example, a fin formed of a III-V semiconductor material grown on a silicon substrate may form defects in a buffer region connecting the III-V semiconductor and the silicon. The random nature of defect formation may result in greater uncertainty as to the resulting height of a semiconductor-grade (i.e., low defect density) portion of the fin.

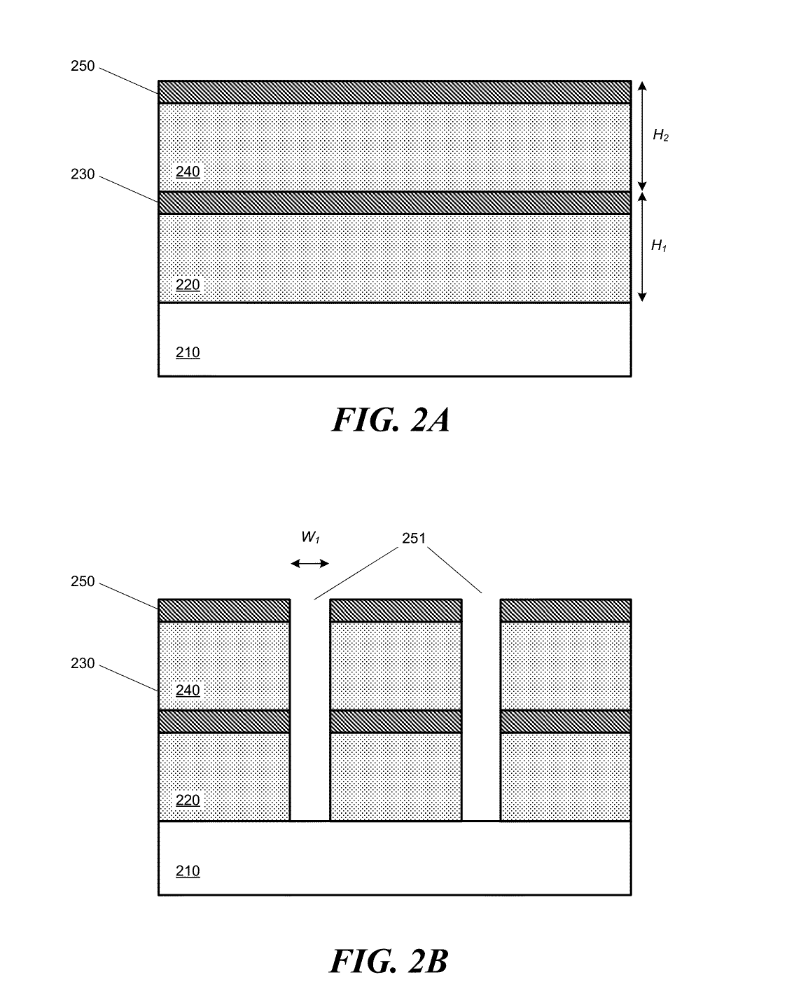

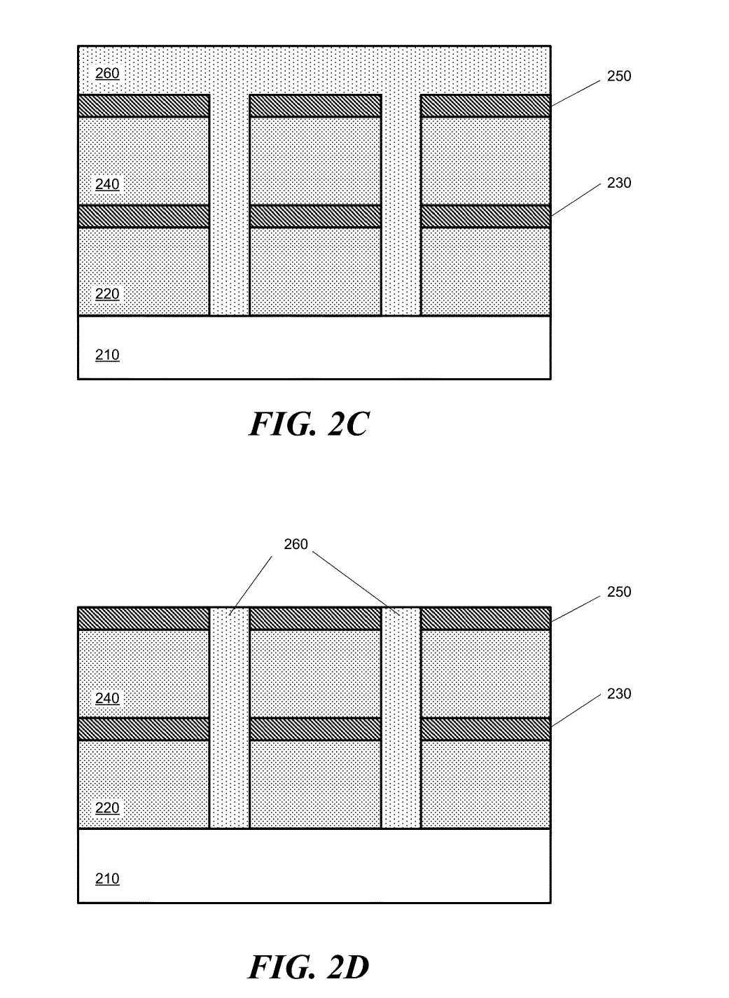

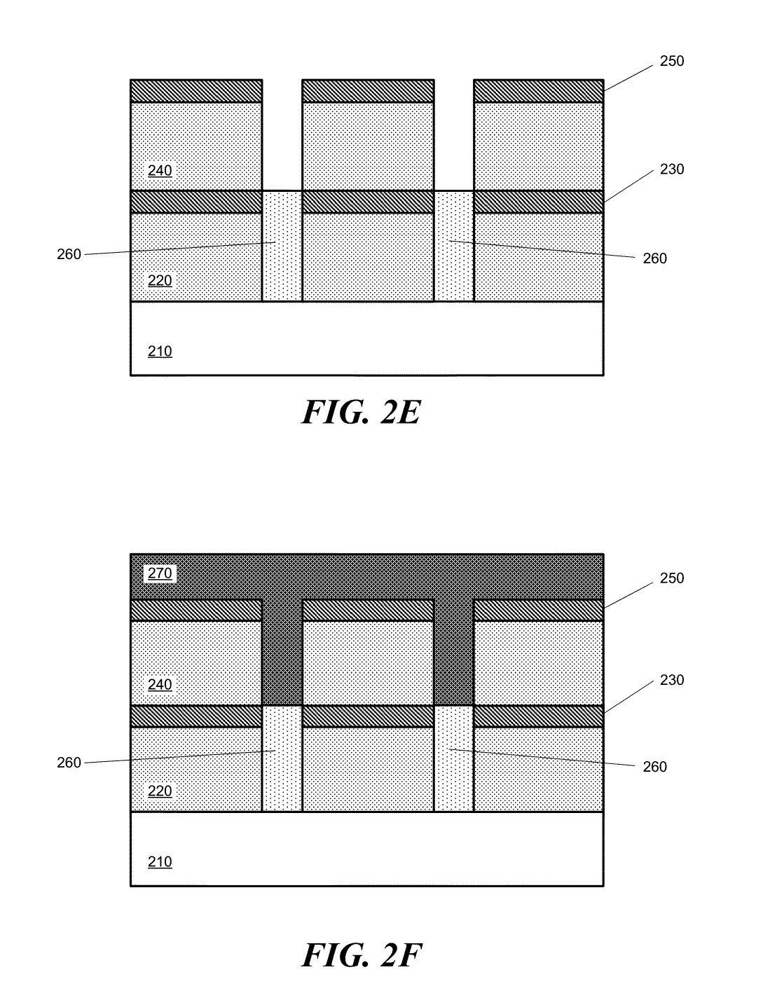

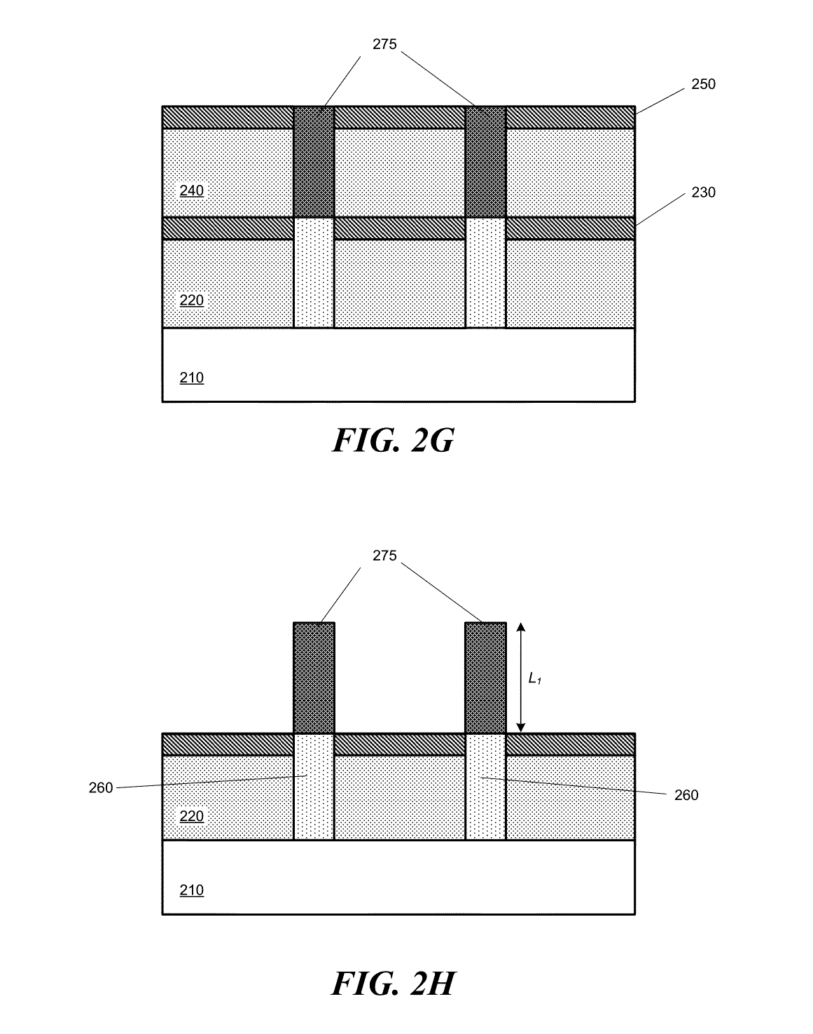

In appreciation of the foregoing, the inventors have conceived of methods and structures for carefully controlling the height of fin structures across a substrate during fin formation. The methods and structures provide a high degree of height consistency in the production of the fins. The methods and structures described herein may be particularly applicable to use cases in which one or more regions of a fin comprise a different semiconductor type than a substrate on which the fin is formed, including embodiments in which a III-V semiconductor fin is formed above a silicon substrate. FIGS. 2A-2H depict process steps that may be used to fabricate a fin structure whilst controlling the height of the fin structure, according to some embodiments. A process for forming a fin structure may begin with a substrate 210, upon which a first spacer 220, first etch-stop layer 230, second spacer 240 and second etch-stop layer 250 have been formed, as depicted in FIG. 2A. In some embodiments, the substrate may comprise a bulk semiconductor substrate 210, which may comprise any suitable semiconductor (e.g., Si, Ge, GaAs, InP, GaN, SiC, etc.), and/or may comprise a material other than a semiconductor. The substrate may comprise a crystalline semiconductor having a standard orientation of crystal planes, or may have any selected rotated orientation (e.g., (110)). In some implementations, an insulating buried oxide layer may be located within substrate 210. For example, substrate 210 may comprise a semiconductor-on-insulator substrate.

According to some embodiments, any of layers 220, 230, 240 and/or 250 may be formed using any suitable deposition processes (e.g., atomic layer deposition, plasma deposition, sputtering, electron-beam evaporation, thermal oxidation). A spacer may be formed from a single material or layers of different materials. First spacer 220 and second spacer 240 may be formed of the same material or materials, or may be formed from different materials. The processes used to deposit the spacers may be the same or different. For example, first spacer 220 may be thermally grown onto substrate 210, and second spacer 240 may be formed via atomic layer deposition or plasma deposition subsequent to forming first etch-stop layer 230 over first spacer 220. First etch-stop layer 230 and second etch-stop layer 250 may be formed of the same material, or may be formed from different materials, using a same process or different processes. In various embodiments, the first and second etch-stop layers exhibit etch selectivity over at least the second spacer 240.

In some embodiments, one or more of first spacer 220 and second spacer 240 comprise a silicon oxide, which may include any compound formed from molecules having any relative amounts of silicon and oxygen (e.g., SiOₓ, where X may have any value). In some embodiments, one or more of first etch-stop layer 230 and second etch-stop layer 250 comprise a silicon nitride, which may include any compound formed from molecules having any relative amounts of silicon and nitrogen (e.g., SiNₓ, where X may have any value). In some implementations, the first and second etch-stop layers may comprise SiOₓ and the first and second spacers may comprise SiNₓ. In the example of FIG. 2A, first spacer 220 and first etch-stop layer 230 have a combined height H₁, and second spacer 240 and second etch-stop layer 250 have a combined height H₂. As described below, height H₁ and/or H₂ may be chosen based on the desired height of fins to be formed later in the process illustrated by FIGS. 2A-2H. In some implementations, the first spacer and first etch-stop layer 230 have a total thickness (e.g., H₁ in the vertical direction in the example of FIG. 2A) between 10 nm and 40 nm, and in some implementations have a thickness between 20 nm and 30 nm. In some implementations, the second spacer 240 and second etch-stop layer 250 have a total thickness between 10 nm and 60 nm, and in some cases, between 20 nm and 40 nm. In some implementations, the second spacer 240 and second etch-stop layer have a total thickness between 25 nm and 35nm, such as 30 nm.

As illustrated in FIG. 2B, trenches 251 may be formed through layers 220, 230, 240 and 250. The trenches 251 may be formed using any suitable process. In some embodiments, one or more trenches are formed using one or more lithographic techniques such as an adapted mandrel or sidewall-image-transfer process. An SIT process may be referred to as a self-aligned double patterning (SADP) process. In some embodiments, a sidewall image transfer (SIT) process may be used to pattern narrow lines of a hard mask. An image reversal process may be used to reverse the narrow line hard mask to a mask having narrow gaps between wider lines. According to some embodiments, interferometric lithography, direct patterning, imprint lithography, high-resolution forms of photolithography, x-ray lithography, or EUV lithography may be used to pattern a mask to form the trenches. In some implementations, process biasing techniques may be used to obtain a mask for etching the narrow trenches. In some implementations, a mask for the narrow trenches may be formed using a double patterning process, e.g., resist-on-resist patterning techniques (which may include a lithography-etch-lithography-etch (LELE) process or a lithography-freeze-lithography-etch (LFLE) process).

Once a mask is formed having a pattern for the trenches 251, one or more selective etches (e.g., reactive ion etches) may be used to remove one or more of layers 220, 230, 240 and 250. In some embodiments, a plurality of trenches may be formed across a substrate using the same process, or using different processes for different trenches. The substrate may comprise a single semiconductor die or a large number of semiconductor die. Moreover, any number of processes may be used to form a single trench, including any of the processes indicated above.

As depicted in FIG. 2B, trenches 251 have a width W₁, which may be any suitable size. In some implementations, the width of trench 251 is between 4 nm and 20 nm, such as between 5 nm and 10 nm, including 5 nm or 7 nm. In some implementations, the width of trench 251 may be approximately 7 nm. Trenches 251 may have any suitable length. In some embodiments, the trenches may have a length between approximately 100 nm and 2 microns (μm).

As used herein, “approximately,” or an “approximate” distance indicates the dimension is accurate to within 10% in some embodiments, to within 5% in some embodiments, and to within 2% in some embodiments. For example, “approximately 7 nm” may refer to a distance between 6.3 nm and 7.7 nm, in some embodiments.

Trenches formed in a single substrate may have the same width, though may also be formed with the intention of forming trenches having different widths (e.g., one or more 5 nm trenches and one or more 7 nm trenches). In addition, trenches formed on a single substrate may exhibit a range of widths due to the inherent precision in the technique(s) used to form the trenches.

In some implementations, a buffer layer 260 may be deposited in one or more of the trenches, as shown in FIG. 2C. The buffer layer 260 may, in some implementations, be epitaxially grown. In some embodiments, the buffer layer comprises a III-V semiconductor, such as InP, InAs, AN, AlGaAs, or GaAs and may or may not be of the same composition as the substrate 210. In some embodiments, other materials may be used for the buffer layer.

According to some embodiments, the buffer layer 260 is planarized to the position of the second etch-stop layer 250, as shown in FIG. 2D. The buffer layer 260 may be etched or polished back (e.g., using chemical-mechanical polishing (CMP)) to the second etch-stop layer 250 which may, in some cases, provide an etch stop for the etching or polishing step. The buffer layer need not be removed to precisely the level of the upper surface of etch-stop layer 250, but may be approximately removed to that level. In some cases, the buffer layer 260 may be etched back to a level just below the second etch-stop layer 250, e.g., within about 5 nm from the upper surface of the second etch-stop layer in some embodiments, and even within about 2 nm from the upper surface of the second etch-stop layer in some embodiments.

The buffer layer 260 may then be etched back to approximately the height of the first etch-stop layer 230, resulting in a structure depicted in FIG. 2E. The etch used may be a timed etch, e.g., a timed reactive ion etch at a known etch rate. In various embodiments, the thicknesses of the spacers 220, 240 and etch-stop layers 230, 250 are carefully controlled during their deposition process so that they are known with a high degree of accuracy. Additionally, they may be determined after deposition from a dummy sample or via direct measurement, e.g., using ellipsometry. In some embodiments, the spacing between the first and second etch-stop layers is known to within 2 nm or less. Because this spacing is known with a high degree of precision, the etch may be timed based upon a known etch rate of the buffer layer to etch the buffer layer back to the first etch-stop layer 230 with a high degree of precision. In some implementations, the buffer layer 260 may be etched back to the first etch-stop layer 230 to within 4 nm or less.

The buffer layer may be formed and etched back such that high densities of crystal defects that exist in the buffer layer due to the buffer layer and substrate 210 being of different semiconductor types (e.g., type IV and type III-V) are substantially limited to regions of the buffer layer near the substrate. In various embodiments, the location of the first etch-stop layer 230 is selected so that the height of the remaining buffer layer 260 (approximately H₁ with reference to FIG. 2A) is greater than an extent of unacceptable defect density levels in the buffer layer. Defects may be formed in the buffer layer during its growth and may be trapped and dissipate at upper regions of the buffer layer. For example, an upper region of the remaining buffer layer may have a defect density approximately equal to or less than 10⁵ cm⁻² according to some embodiments. In some embodiments, subsequent formation of the semiconductor fin on the buffer layer may occur with lower defect densities.

In some implementations, the upper surface of the buffer layer after etching may not necessarily be at the precise location of the upper surface of the first etch-stop layer. The upper surface of the buffer layer after etching may be within ±10 nm of the location of the upper surface of the first etch-stop layer in some implementations, within ±5 nm of the location of the upper surface of the first etch-stop layer in some implementations, and yet within ±2 nm of the location of the upper surface of the first etch-stop layer in some implementations.

A semiconductor layer may then be formed in one or more of the trenches, as shown in FIG. 2F. The semiconductor layer 270 may, in some implementations, be epitaxially grown on the buffer layer 260. In some embodiments, the semiconductor layer 270 comprises a III-V semiconductor, such as InP, InAs, GaN, or InGaAs, and may or may not be of the same composition as the substrate 210 or the buffer layer 260. In some embodiments, the semiconductor layer 270 is of the same semiconductor type as the buffer layer 260 (e.g., type III-V). The semiconductor layer may be planarized to the position of the second etch-stop layer, as shown in FIG. 2G. According to some embodiments, the semiconductor layer 270 may be etched or polished back (e.g., using chemical-mechanical polishing (CMP)) to the second etch-stop layer 250 which may, in some cases, provide an etch stop for the etching or polishing step. The same process(es) or different process(es) may be used to etch or polish back semiconductor layer 270 as was used to etch or polish back buffer layer 250 as shown in FIG. 2D. Removal of the excess semiconductor material leaves fins 275, as depicted in FIG. 2G. As may be appreciated, the height of the fins 275 can be determined quite precisely by the location of the second etch-stop layer 250. The height of the fins 275 may not be precisely the same for each trench, but in general may be approximately the height of the upper surface of the etch-stop layer 250 after planarization. The upper surface of the fins may be within ±5 nm of the upper surface of the second etch-stop layer 250 in some embodiments, within ±2 nm of the upper surface of the second etch-stop layer 250 in some embodiments, and yet within ±1 nm of the upper surface of the second etch-stop layer 250 in some embodiments.

It may be appreciated from the foregoing description that the height of the fins 275 and their upper surfaces can be highly uniform across large areas of a wafer or substrate, and highly uniform across a semiconductor die. This is because the deposition processes for spacers 220, 240 and etch-stop layers 230, 250 provide highly uniform thicknesses across large areas. With reference to FIG. 2D, the starting height for the buffer layer prior to its etch back can be highly uniform across large areas (e.g., within ±5 nm in some embodiments, within ±2 nm in some embodiments, and yet within ±1 nm in some embodiments). Such uniformity may be obtained across areas as large as 10 mm in diameter in some embodiments, across areas as large as 20 mm in diameter in some embodiments, across areas as large as 50 mm in diameter in some embodiments, across areas as large as 100 mm in diameter in some embodiments, across areas as large as 200 mm in diameter in some embodiments, and yet across areas as large as 400 mm in diameter in some embodiments. Although the etch back of the buffer layer (depicted in FIG. 2E) may result in some height variation of the buffer layer 260 within the trenches, the upper surface of the fins 275 is determined by the location of the second etch-stop layer 250. Accordingly, the uniformity in height of the upper fin surface above the substrate 210 will be equally determined by the uniform thicknesses of the spacer and etch-stop layers (e.g., within ±5 nm in some embodiments, within ±2 nm in some embodiments, and yet within ±1 nm in some embodiments).

The second etch-stop layer 250 and spacer 240 may be etched back to approximately the height of the first etch-stop layer 230, as shown in FIG. 2H. Fins are thereby revealed, having an approximate height L₁ as shown in the figure. The second etch-stop layer 250 and spacer 240 may be removed using any suitable process or processes, e.g. dry and/or wet etch processes. For example, a first wet etch may be performed which selectively etches the etch-stop layer 250 but does not appreciably etch the fins 275 or spacer 240, and a second dry etch may be performed to selectively remove the spacer 240. As may be appreciated, the amount of fin revealed may be highly uniform since it is determined primarily be the thicknesses of the second spacer 240 and second etch-stop layer 250. There may be some variability in the location of the bottom surface of the fin 275, that depends upon spatial non-uniformities of the etching process used to etch back the buffer layer 260, as depicted in FIG. 2D.

As described above, in cases where the buffer layer and semiconductor layer are of the same semiconductor type as each other, but are of a different type than the substrate, the structure shown in FIG. 2H may exhibit little or no defects in the semiconductor layer due to the defects substantially terminating within the buffer layer. For example, crystal defects may propagate from the interface between the buffer layer and the substrate within the buffer layer, but may not propagate through the buffer layer as far as the interface with the semiconductor layer.

Although the processes described above have been directed primarily to fins formed from III-V semiconductor material, the processes may be used to form fins of highly uniform height from other materials. In some implementations, bulk semiconductor material may be used. In some implementations, II-VI semiconductor material may be used. In some cases, two materials which are not semiconductors may be formed in trenches to have highly uniform heights across large areas.

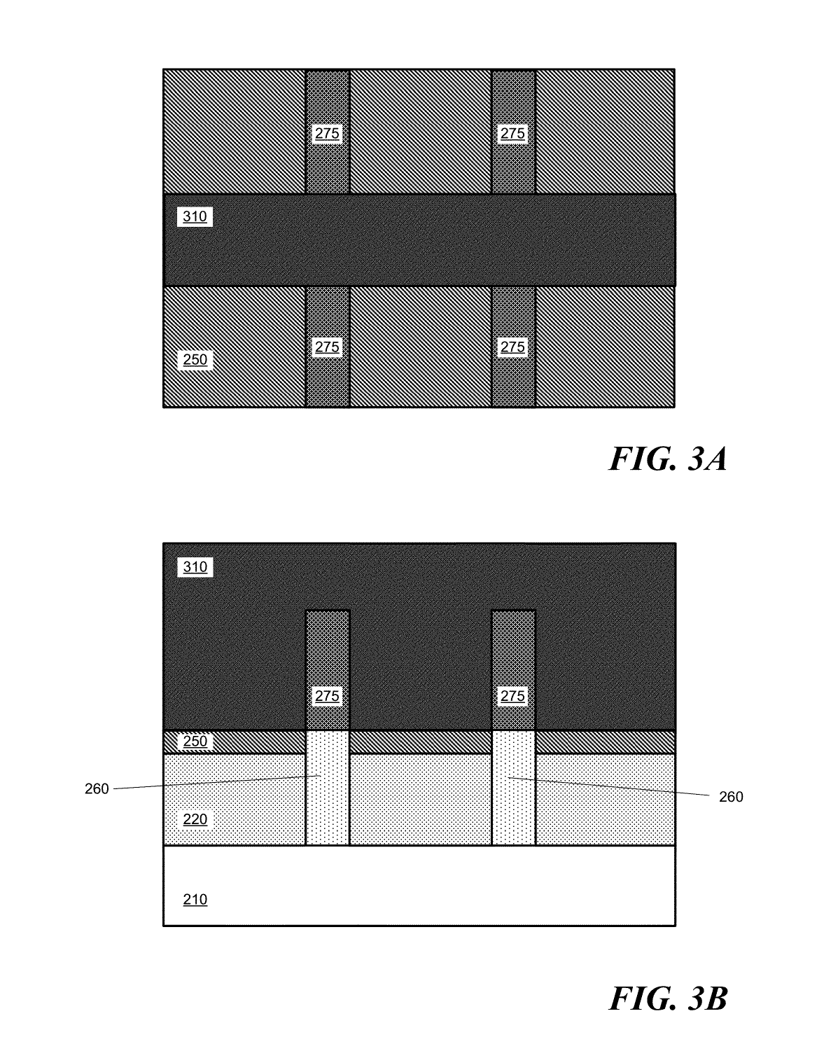

According to some embodiments, a finFET may be formed from the fin structure shown in FIG. 2H. A thin gate insulator (e.g., an oxide or high-K dielectric, not shown) and gate material 310 may be formed over the fins, as depicted in FIGS. 3A-B. Gate material 310 has been formed over a central region of the fins 270, as shown in the plan view of FIG. 3A and the side view of FIG. 3B. The gate material may be formed of any suitable material. In some embodiments, the gate material comprises a high conductive material, such as, but not limited to, tungsten or a tungsten silicide. In some embodiments, the gate conductor may be formed from polysilicon. Source and drain regions of the fins may be doped to have a particular conductivity type, e.g., n-type or p-type. Electrical interconnects may be made to the source, drain, and gate regions.

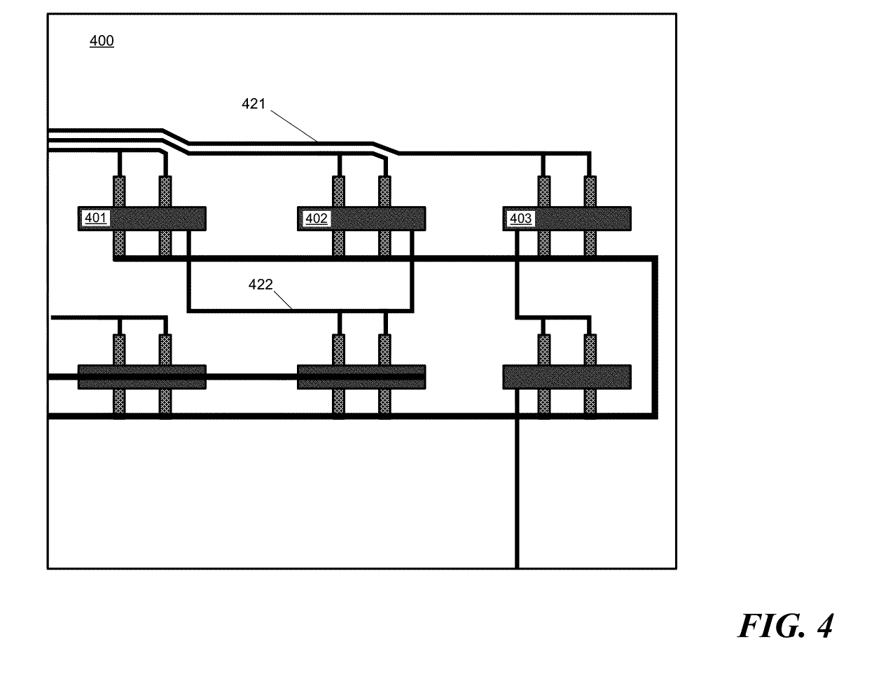

According to some embodiments, one or more fin structures having uniform heights and uniform reveal heights as described above may be formed on a single semiconductor die. For example, a plurality of finFETs having two or more fins as shown in FIGS. 3A-B may be formed on a single die and distributed across the die in any manner, as depicted in FIG. 4. FinFETs 401-403 are exemplary finFETs formed on semiconductor die 401. In the example of FIG. 4, interconnects 421 and 422 are provided as illustrative connections between the finFETs. It will be appreciated that the example of FIG. 4 is simplified for illustrative purposes and that a semiconductor die may have thousands of finFETs, possibly in addition to other structures, formed on it. In addition, the semiconductor die may include finFETs have a structure different from that shown in FIG. 4 (e.g., having only a single fin or continuous connected gate structures).

According to some embodiments, the height of the fins across the semiconductor die may be substantially consistent. For example, the height of the fins may be within ±2 nm of each other. In some implementations, the height of the fins may be within ±1 nm of each other.

Although the foregoing methods and structures are described in connection with “finFETs,” the methods and structures may be employed for variations of finFET devices in some embodiments. For example, according to some implementations, the methods and structures may be employed for the fabrication of tri-gate, pi-gate, or omega-gate transistors. In some embodiments, the methods and structures may be employed for the fabrication of gate-all-around (GAA) transistors.

The technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Additionally, a method may include more acts than those illustrated, in some embodiments, and fewer acts than those illustrated in other embodiments.

Although the drawings depict one or a few transistor structures, it will be appreciated that a large number of transistors can be fabricated in parallel following the described semiconductor manufacturing processes. The transistors may be incorporated as part of microprocessing or memory circuitry for digital or analog signal processing devices. The transistors may be incorporated in logic circuitry, in some implementations. The transistors may be used in consumer electronic devices such as smart phones, computers, televisions, sensors, microprocessors, microcontrollers, field-programmable gate arrays, digital signal processors, application specific integrated circuits, logic chips, analog chips, and digital signal processing chips.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A method, comprising:
forming one or more trenches in a multi-layer structure comprising a first etch-stop layer and a second etch-stop layer, the one or more trenches formed through the first and second etch-stop layers;
forming a first layer in at least a first trench of the one or more trenches, wherein the first layer fills at least the first trench to a level approximately at a position of the first etch-stop layer;
forming a semiconductor layer different from the first layer in at least the first trench.

2. The method of claim 1, further comprising:
removing a portion of the semiconductor layer; and
stopping the removal at the second etch-stop layer, wherein the remaining semiconductor layer fills at least the first trench to a level approximately at a position of the second etch-stop layer.

3. The method of claim 2, further comprising:
etching the multi-layer structure to remove the second etch-stop layer and a spacer; and
stopping the etching at the first etch-stop layer.

4. The method of claim 3, wherein the etching exposes the semiconductor layer so as to form at least a first fin for a finFET.

5. The method of claim 1, wherein forming the one or more trenches comprises etching the one or more trenches in shapes for forming one or more fins for one or more finFETs.

6. The method of claim 5, further comprising:
depositing the first etch-stop layer;
depositing, on the first etch-stop layer; a spacer having a thickness approximately equal to a selected fin height; and
depositing the second etch-stop layer on the spacer.

7. The method of claim 6, wherein the spacer comprises a silicon oxide.

8. The method of claim 6, wherein at least one of the first etch-stop layer and the second etch-stop layer comprises a silicon nitride.

9. The method of claim 5, further comprising forming a width of at least one trench to be between approximately 4 nm and approximately 20 nm.

10. The method of claim 1, wherein the first layer comprises a buffer layer.

11. The method of claim 10, wherein the buffer layer is InP.

12. The method of claim 1, wherein the semiconductor layer comprises a III-V semiconductor material.

13. The method of claim 12, wherein the III-V semiconductor material is InGaAs.

14. The method of claim 1, further comprising etching the one or more trenches to a semiconductor substrate.

15. The method of claim 14, wherein the first layer comprises a first semiconductor material and forming the first layer comprises:
depositing the first semiconductor material to overfill at least the first trench;
planarizing the first semiconductor material to approximately a level of the second etch-stop layer; and
performing an etch to recess the first semiconductor material to approximately a level of the first etch-stop layer.

16. The method of claim 15, further comprising:
depositing a first spacer on the substrate; and
depositing the first etch-stop layer on the first spacer, wherein
the thickness of the first spacer is selected such that crystal defects in the first semiconductor material terminate at approximately the first etch-stop layer.

17. The method of claim 15, wherein forming the semiconductor layer comprises:
growing a second semiconductor material to overfill at least the first trench in contact with the first semiconductor material; and
planarizing the second semiconductor material to approximately the level of the second etch-stop layer.

18. A structure for forming a finFET, comprising:
a substrate;
a first etch-stop layer spaced a first distance from a surface of the substrate;
a second etch-stop layer spaced a second distance from the first etch-stop layer;
at least a first trench formed through the first etch-stop layer and the second etch-stop layer;
a buffer layer in contact with the substrate and filling at least the first trench approximately to a level of the first etch-stop layer; and
a semiconductor layer in contact with the buffer layer.

19. The structure of claim 18, wherein the semiconductor layer fills the trench approximately to a level of the second etch-stop layer.

20. The structure of claim 18, further comprising a spacer separating the second etch-stop layer from the first etch-stop layer.

21. The structure of claim 20, wherein the spacer has a thickness between approximately 10 nm and approximately 60 nm.

22. The structure of claim 20, wherein the spacer comprises silicon oxide.

23. The structure of claim 18, wherein the buffer layer comprises a first III-V semiconductor material.

24. The structure of claim 23, wherein the first III-V semiconductor material is InP.

25. The structure of claim 18, wherein the semiconductor layer comprises a second III-V semiconductor material.

26. The structure of claim 25, wherein the second III-V semiconductor material is InGaAs.

27. The structure of claim 18, wherein the semiconductor layer has a width between 4 nm and 20 nm and a height between 10 nm and 60 nm out of the trench.

28. The structure of claim 18, wherein the semiconductor layer has a substantially rectangular cross-section.

29. The structure of claim 18, wherein the first etch-stop layer comprises silicon nitride.

30. A semiconductor die comprising a plurality of fins for finFETs distributed over the die wherein each of the plurality of fins are formed from a buffer layer and a semiconductor layer formed on the buffer layer, wherein a height of the fins across the semiconductor die is the same to within ±2 nm.

31. The semiconductor die of claim 30, wherein the height of the fins across the semiconductor die is the same to within ±1 nm.

32. The semiconductor die of claim 30, wherein the buffer layer is an epitaxial layer formed on a substrate.

33. The semiconductor die of claim 32, wherein the buffer layer comprises a III-V semiconductor and the substrate comprises silicon.

34. The semiconductor die of claim 33, wherein the III-V semiconductor is InP.

35. The semiconductor die of claim 32, wherein defects resulting from epitaxial growth are reduced to 10⁵ cm⁻² or less than this value within the buffer layer.

36. The semiconductor die of claim 30, wherein the semiconductor layer comprises a III-V semiconductor.

37. The semiconductor die of claim 36, wherein the III-V semiconductor is InGaAs.

38. The semiconductor die of claim 30, wherein the semiconductor die has a lateral extent greater than 10 mm.
